(19) United States
(12) Patent Application Publication
(10) Pub. No.: US 2010/0201880 A1
(43) Pub. Date: Aug. 12, 2010

(54) SHOT SIZE IDENTIFYING APPARATUS AND METHOD, ELECTRONIC APPARATUS, AND COMPUTER PROGRAM

(75) Inventor: Hiroshi Iwamura, Saitama (JP)

Correspondence Address: YOUNG & THOMPSON, 209 Madison Street, Suite 500, Alexandria, VA, 22314, US

(73) Assignee: PIONEER CORPORATION, TOKYO (JP)

(21) Appl. No.: 12/595,441

(22) PCT Filed: Apr. 13, 2007
(86) PCT No.: PCT/JP2007/058158

§ 371 Date: Oct. 9, 2009

(51) Int. Cl. G06K 9/48; H03M 1/12

(52) U.S. Cl. 348/573; 382/199; 348/E05.062

(57) ABSTRACT

A shot size identifying device (1) includes an edge detecting element (102) for detecting edges in a frame constituting a video, a connected edge area detecting element (103) for detecting connected edge areas in which the detected edges are connected, an edge area counting element (104) for counting the number of edge areas which is the total number of the detected connected edge areas for each frame, and shot size identifying element (110, 113) for identifying the frame as a long shot if the number of counted edge areas is larger than the threshold value of a first edge area. This makes it possible to easily and immediately identify a shot size.

### TECHNICAL FIELD

The present invention relates to a shot size identifying apparatus and method, an electronic apparatus and a computer program for identifying shot size of motion picture such as video.

### BACKGROUND ART

In the identifying method of this type of apparatus, a shot or a frame imagery in which whole of an object is filmed by such as filming the object from afar is identified as long shots in an image. Alternatively, a shot or a frame imagery in which a part of an object is filmed in close-up by such as filming the object at close range is identified as close-up shots in an image. Moreover, a shot or a frame imagery which is intermediate between long shots and close-up shots is identified as middle shots. By performing the foregoing shot size identifying automatically, it is planed to perform image-editing operations effectively. For example, in a non-patent document 1, the following technique is described: an inclusion relation of shots is judged by applying a camera work detection and an active search method; shot size is given on the basis of the judged inclusion relation.

Non-patent document 1: “Automatic Shot Size Discrimination for a Video Editing Support System”, Journal of Institute of Electronics, Information and Communication Engineers Vol. J85-D-I, No. 7, pp. 592-602, 2002.

### DISCLOSURE OF INVENTION

### Subject to be Solved by the Invention

However, according to the aforementioned background art, there is a technical problem that the amount of an information processing becomes heavy and the same object must be filmed with a similar angle before and after changing shot size because zoom ratio is detected by the active search method. Moreover, there is a technical problem that it is impossible to support if the distance between a camera and an object is change in the same shot size. Moreover, there is a technical problem that there is a possibility that a false detection passes on because an inclusion relation is judged by the camera work detection.

In view of the aforementioned problem, for example, it is therefore an object of the present invention to provide a shot size identifying apparatus and method, an electronic apparatus and computer program which can identify shot size easily and swiftly.

### Means for Solving the Subject

The above object of the present invention can be achieved by first shot size identifying apparatus is provided with: an edge detecting device for detecting edges which exist in each of frames constituting an image; a connected edge area detecting device for detecting connected edge areas where the detected edges are connected; an edge area counting device for counting number of edge areas which is total number of the detected connected edge areas for every the frames; and a shot size specifying device for specifying the frames as long shots if the counted number of edge areas is greater than first threshold for number of edge areas.

According to the first shot size identifying apparatus of the present invention, in its operation, first, edges of a frame are detected for every frames by the edge detecting device, which is composed of such as a processor and a memory. Here, the “frame” means each of a plurality of frame imageries constituting a series of image information by replacing frame frequency. The frame normally forms a single still image. The “edge” means a portion where a value of image data in voluntary one area substantially changes in view of a predetermined criterion as compared with image data in one or a plurality of areas which adjoin or stand close to the one area in each of frames when each of frames is divided into a plurality of areas. The edge typically means a portion where brightness as one of the image data substantially changes in each of frames. This edge may be detected, for example, as follows: the difference value between the brightness value of a target pixel of a plurality of pixels which constitutes a single frame and the brightness value of a pixel which adjoins the target pixel is calculated; and then, the edge is detected by judging whether or not the difference value is greater than a predetermined threshold. At this time, a portion where saturation or color changes in place of or in addition to brightness may be treated as the edge.

Incidentally, it is not limited to performing edge detection every pixels; the edge detection may be performed every blocks which are composed of a plurality of adjoining pixels (e.g. 4 pixels long by 4 pixels width). In the case in which the edge detection is performed every blocks, the brightness value of a block may be maximum of brightness values of pixels included the block, or an average of brightness values of pixels included the block.

Then, a connected edge area where detected edges are connected is detected by the connected edge area detecting device, which is composed of such as a processor and a memory. By this, it is possible to detect outlines of people, constructions and the like which are come out in a frame.

Then, the number of edge areas regarding the detected connected edge area is counted by the edge area counting device, which is composed of such as a processor and a memory.

Then, a frame is specified as long shots by the shot size specifying device, which is composed of such as a processor and a memory if the number of edge areas, which is counted for every frames, is greater than the first threshold for number of edge areas. Inversely, a frame is not specified as long shots if the counted number of edge areas is less than the first threshold for number of edge areas. Here, the “first threshold for number of edge areas” is a value which determines whether or not a frame is long shots. The first threshold for number of edge areas is set as a fixed value in advance or as a changeable value changing according to some parameter. This first threshold for number of edge areas is 60 for example, and is set as a value which can certainly estimate that a frame is long shots. Incidentally, the “long shots” of the present invention mean frames in which whole of an object is filmed from afar in view of a predetermined criterion. Namely, the long shots are shots which are relatively discerned from middle shots and close-up shots. It is arbitrarily set whether a category of long shots includes a shot which is filmed how far from an object or how close to an object in accordance with the purpose or specification of this shot size identifying.

According to the study of the present inventor, it is turned out that in long shots, generally, the number of people or constructions come out in a frame is larger than middle shots and close-up shots, thereby the number of edge areas to be counted is large. Therefore, it is preferable that the first threshold for number of edge areas is set at a value which is moderately greater than the number of edge areas of not only close-up shots but also middle shots. By this, it is possible to reduce a possibility for false specifying or incorrect identification.

In the first shot size identifying apparatus of the present invention, it is specified whether or not a frame is long shots for every frames not by clearing up a mutual relationship between a plurality of frames but in accordance with the result of a statistical processing which uses an edge detection. Namely, in the present invention, a processing which is specialized in specifying whether or not a frame is long shots for every frames is performed. In other words, it is not necessary to perform a complicated and advanced processing such as the camera work detection and the active search method for clearing up a mutual relationship between a plurality of frames. It is said that by eliminating generation of additional data or extra data in a process for achieving an object that it is specified whether or not a frame is long shots for every frames, the present invention achieves this original object through a minimum of or near offer processings. Therefore, it is possible to shorten the amount of time for a series of processing.

As a result, according to the first shot size identifying apparatus of the present invention, it is possible to easily and swiftly identify shot size.

In one aspect of the first shot size identifying apparatus of the present invention, said shot size specifying device is provided with: a judging device for judging whether or not the counted number of edge areas is greater than the first threshold for number of edge areas; and a shot size identifying device for identifying the frames as long shots if it is judged that it is greater than the first threshold for number of edge areas.

According to this aspect, in the shot size specifying device, first, it is judged whether or not the counted number of edge areas is greater than the first threshold for edge areas by the judging device, which is composed of such as a processor and a memory. Then, if it is judged that it is greater than the first threshold for edge areas, a frame is identified as long shots by the shot size identifying device, which is composed of such as a processor and a memory. Thus, it is possible to extremely effectively specify shot size on the basis of the counted number of edge areas.

In another aspect of the first shot size identifying apparatus of the present invention, the first threshold for number of edge areas is determined on the basis of a parameter of the frames.

According to this aspect, since the first threshold for edge areas is determined on the basis of a parameter such as resolution of a frame, it is possible to identify shot size without influence of the setting for filming of such as a video camera, so that it is extremely useful in practice.

In another aspect of the first shot size identifying apparatus of the present invention, the first threshold for number of edge areas is changeable in accordance with a parameter indicating a predetermined statistical value of the frames.

According to this aspect, the first threshold for number of edge areas is set as the sum of an average of number of edge areas and a standard deviation, for example, concerning all of a plurality of frames constituting an image or concerning frames which are performed a processing of shot size identifying up to now. Or, the first threshold for number of edge areas is set as a value in accordance with the sum. It is possible to more adequately set the first threshold for number of edge areas from the beginning if a statistical value is adopted as a previous image whose type or property is identical with or similar to the image which is a target for current identifying. Alternatively, it is possible to more adequately set the first threshold for number of edge areas in the future if a previous statistical value of the image which is a target for current identifying is adopted.

In another aspect of the first shot size identifying apparatus of the present invention, the shot size specifying device specifies the frames as middle shots if the counted number of edge areas is less than second threshold for number of edge areas.

According to this aspect, a frame is specified as middle shots if it is judged that the counted number of edge areas is less than the second threshold for number of edge areas by the shot size specifying device. Here, the “second threshold for number of edge areas” is a value which determines whether or not a frame is middle shots. The second threshold for number of edge areas is set as a fixed value in advance or as a changeable value changing according to some parameter. This second threshold for number of edge areas is 20 for example, and is set as a value which can certainly estimate that a frame is not long shots.

In this aspect, the second threshold for number of edge areas may be less than the first threshold for number of edge areas.

By virtue of such construction, it is possible to certainly specify frames which are not long shots, so that it is possible to improve reliability of identifying results.

In another aspect of the first shot size identifying apparatus of the present invention, the first shot size identifying apparatus is further provided with: a noise removing device for removing noise of each of the frames.

According to this aspect, it is possible to reduce possibility that the number of edge areas fluctuates due to noise existing on a frame, so that it is possible to improve reliability of identifying results.

The above object of the present invention can be achieved by second shot size identifying apparatus is provided with: a flatness calculating device for calculating index values indicating flatness in each of frames constituting an image for every predetermined units which are composed of one pixel or a plurality of adjoining pixels constituting each of the frames; a binarizing device for converting the calculated index values into binary; a large flat area specifying device for specifying areas where total number of the predetermined units is greater than or equal to a predetermined threshold as large flat areas from connected flat areas where the predetermined units of which the binary index value is identical are connected; and a shot size specifying device for specifying the frames which have the specified large flat areas as long shots if at least one of a plurality of evaluation items preliminarily determined in regard to the specified large flat areas meets a predetermined condition.

According to the second shot size identifying apparatus of the present invention, in its operation, first, index values indicating flatness in each of frame imageries constituting an image are calculated for every predetermined units by the flatness calculating device, which is composed of such as a processor and a memory. Here, the “predetermined unit” of the present invention may be one pixel constituting a single frame or a frame imagery, or may be a block which is composed of a plurality of pixels (e.g. 16 pixels long by 16 pixels width).

Incidentally, the “flatness” of the present invention means the difference between the parameter, such as color density value and brightness value, of a target predetermined unit and the parameter of another predetermined unit, which adjoins the target predetermined unit or exists within a predetermined range, is little. This flatness is concept contrasted with the aforementioned edges.

Moreover, the “index value” of the present invention is a value indicating a degree of flat quantitatively, and is obtained in accordance with a predetermined arithmetic expression by using one or a plurality of parameters such as color density value and brightness value. This index value may be, specifically, for example, obtained as follows: the absolute value of the difference value between the value of a predetermined parameter of a target predetermined unit and value of the predetermined parameter of each of a plurality of predetermined units, which adjoin the target predetermined unit, is calculated; the index value is specified by obtaining the average of the absolute values.

Then, calculated index values are converted into binary by the binarizing device, which is composed of such as a processor and a memory. It is preferable that a threshold for binarizing is set as moderately small value.

By this, it is possible to reduce possibility of false detection. Incidentally, the flatter, the index value is the smaller. Thus, in binarizing, the index value is 1 if the index value is less than the threshold; and the index value is 0 if the index value is greater than the threshold.

Then, areas where the total number of the predetermined units is greater than or equal to a threshold for number of units as the predetermined threshold is specified as large flat areas from connected flat areas where the predetermined units of which the binary index value is identical (typically, the binary index value is 1) are connected by the large flat area specifying device, which is composed of such as a processor and a memory. Incidentally, detection or specifying of connected flat areas is performed by a labeling processing or the like. Moreover, the “threshold for number of units” is a value which determines whether or not the connected flat area is large flat areas. The threshold for number of units is typically set as a fixed value in advance, but the threshold for umber of units may be as a changeable value changing according to some parameter. Alternatively, a user defines long shots, thereby the threshold for number of units is set manually. This threshold for number of units depends on the predetermined unit. For example, the threshold for number of units is 200 blocks if the resolution of an image is 480 pixels long by 720 pixels width and if the predetermined unit is the block with 16 pixels long by 16 pixels width. The threshold for number of units is set as a value which can estimate that a frame is considered for long shots.

Then, the frame which has the aforementioned specified large flat areas is specified as long shots by the shot size specifying device, which is composed of such as a processor and a memory if at least one of a plurality of evaluation items preliminarily determined in regard to the specified large flat areas meets a predetermined condition. Inversely, the frame which has the aforementioned specified large flat areas is not specified as long shots if all of the plurality of evaluation items preliminarily determined in regard to the specified large flat areas does not meet the predetermined condition. Here the “evaluation item” is, for example, the shape of the large flat area, the position of the large flat area on a frame and the like. Moreover, the “predetermined condition” is a condition which determines whether or not a frame is long shots. The predetermined condition is set as a condition which can certainly estimate a frame is long shots.

Incidentally, when there are a plurality of specified large flat areas, for example, (i) if at least one of a plurality of evaluation items in regard to a large flat area which has the largest area meets a predetermined condition, a frame which has the large flat area may be specified as long shots, or (ii) the plurality of areas are estimated, and then if at least one of the plurality of areas meets a predetermined condition corresponding to at least one of a plurality of evaluation items, a frame which has the large flat area may be specified as long shots.

In the second shot size identifying apparatus of the present invention, it is specified whether or not a frame is long shots for every frames not by clearing up a mutual relationship between a plurality of frames but in accordance with results of the statistical processing using the binarizing.

Therefore, it is possible to shorten the amount of time for a series of processing in a similar way to the aforementioned first shot size identifying apparatus.

As a result, according to the second shot size identifying apparatus of the present invention, it is possible to easily and swiftly identify a shot size.

In one aspect of the second shot size identifying apparatus, said large flat area specifying device is provided with: a connected flat area detecting device for detecting the connected flat areas; and a large flat area extracting device for extracting areas where number of the predetermined units is greater than or equal to the threshold for number of units as large flat areas of the detected connected flat areas.

In this aspect, in the large flat area specifying device, first, predetermined units which have identical binary index value are extracted, and an area where extracted predetermined units are connected is detected by the connected flat area detecting device, which is composed of such as a processor and a memory. Then, an area where the number of predetermined units included in detected areas is greater than the threshold for number of units is extracted as large areas by the large flat area extracting device, which is composed of such as a processor and a memory. Thus, it is possible to extremely effectively specify large flat areas on the basis of binary index values.

In another aspect of the second shot size identifying apparatus of the present invention, said shot size specifying device is provided with: a judging device for judging the extracted large flat areas are whether or not the at least one meets the predetermined condition; and a shot size identifying device for identifying frames which have the extracted large flat areas as long shots if it is judged that it meets the predetermined condition.

In this aspect, in the shot size specifying device, first, a plurality of evaluated values corresponding to a plurality of evaluation items are given to an extracted large flat area by the evaluating device, which is composed of such as a processor and a memory. The evaluation item is, for example, the horizontal width of a rectangle which is circumscribed the large area if the evaluation item concerns the shape of large flat areas. Alternatively, the evaluation item is the coordinates of the barycentric position of the large flat area on a frame, or the coordinates of one or a plurality of apexes of a rectangle which is circumscribed the large flat area if the evaluation item concerns positions on a frame. Next, it is judged whether or not at least one of the plurality of given evaluation items meets a predetermined condition corresponding to the evaluation item by the judging device, which is composed of such as a processor and a memory. Then, if it is judged that it meets the predetermined condition, a frame which has the extracted large flat area is identified as long shots by the shot size identifying device, which has such as a processor and a memory. Thus, it is possible to extremely effectively specify the shot size on the basis of specified large flat area.

In another aspect of the second shot size identifying apparatus of the present invention, the plurality of evaluation items includes area ratio between area of the extracted large flat area and area of a rectangle which is circumscribed the extracted large flat area, and the predetermined condition is that the area ratio is greater than or equal to an area ratio threshold.

According to this aspect, the plurality of evaluation items includes area ratio between area of the extracted large area and area of a rectangle which is circumscribed the extracted large area. In this case, the evaluating device, for example, gives the area ratio as the evaluated value.

The “area ratio threshold” is a value which determines whether or not a frame is long shots. The area ratio threshold is typically set as a fixed value in advance, but the area ratio threshold may be set as a changeable value changing according to some parameter. This area ratio threshold is 0.4 for example, and is set as a value which can certainly estimate that a frame is long shots. Incidentally, the “area ratio” and the “area ratio threshold” may be expressed in not only ratio but also percentage or fraction.

In another aspect of the second shot size identifying apparatus of the present invention, the plurality of evaluation items includes a horizontal width of a rectangle which is circumscribed the extracted large flat area, and the predetermined condition is that the horizontal width is greater than or equal to a horizontal width threshold.

According to this aspect, the plurality of evaluation items includes a horizontal width of a rectangle which is circumscribed the extracted large flat area. In this case, the evaluating device, for example, gives the horizontal width as the evaluated value.

The “horizontal width” is a value which determines whether or not a frame is long shots. The horizontal width threshold is typically set as a fixed value in advance, but the horizontal width threshold may be set as a changeable value changing according to some parameter. This horizontal width threshold is, for example, 30 blocks if the resolution of an image is 480 pixels long by 720 pixels width and if the predetermined unit is 16 pixels long by 16 pixels width. The horizontal width threshold is set as a value which can certainly estimate that a frame is long shots. Incidentally, the “horizontal width” and the “horizontal width threshold” may be an absolute value, or ratio, fraction or percentage of some parameter.

In another aspect of the second shot size identifying apparatus of the present invention, the plurality of evaluation items includes a barycentric position of the extracted large flat area, and the predetermined condition is that the barycentric position is a predetermined range.

According to this aspect, the plurality of evaluation items includes a barycentric position of the extracted large flat area. In this case, the evaluating device, for example, gives the barycentric position as the evaluated value. Incidentally, the “barycentric position” is typically expressed in a coordinate value in a frame. The “barycentric position” may be an absolute value, or ratio, fraction or percentage of some parameter.

The “predetermined range” is a range which determines whether or not a frame is long shots. The predetermined range is typically set as a fixed value in advance, but the predetermined range may be set as a changeable value changing according to some parameter. This predetermined range is, for example, within upper one third of a frame or within lower one third of a frame. The predetermined range is set as a range which can certainly estimate that a frame is long shots. In another aspect of the second shot size identifying apparatus of the present invention, said flatness calculating device calculates the index values by performing frequency analysis on each of the predetermined units.

According to this aspect, the flatness calculating device applies the frequency analysis to image signals indicating a color density value or a brightness value of a predetermined unit in a frame. Then, the flatness calculating device calculates an index value by obtaining the ratio between a lower frequency component and a higher frequency component not including the lower frequency component on the basis of the result of the performed frequency analysis.

In this aspect, the frequency analysis may include two-dimensional discrete cosine transform or discrete Fourier transform.

By virtue of such construction, it is possible to relatively effectively calculate high accuracy index values.

In another aspect of the second shot size identifying apparatus of the present invention, the second shot size identifying apparatus is further provided with: a number of flat areas counting device for counting number of flat areas in each of the detected connected flat areas, said shot size specifying device specifying frames which have the extracted large flat areas as long shots if the counted number of flat areas is less than or equal to a threshold for number of flat areas when the at least one meets the predetermined condition.

According to this aspect, the number of flat areas counting device, which is composed of such as a processor and a memory, counts the number of flat areas of the extracted flat areas. According to the study of the present inventor, it is turned out that a few flat areas, which dominates relatively large area, are detected in long shot frames which are filmed under low light condition such as night or at a place with a fine view such as a coast. Therefore, by counting the number of flat areas of detected flat areas, it is possible to certainly judge whether or not a frame is long shots, so that it is possible to improve reliability of specified results.

Incidentally, the “threshold for number of flat areas” is a value which determines whether or not a frame is long shots. The threshold for number of flat areas is typically set a fixed value in advance, but the threshold for number of flat areas may be set a changeable value changing according to some parameter. This threshold for number of flat areas is set as a value which can certainly estimate that a frame is long shots.

In another aspect of the second shot size identifying apparatus of the present invention, the second shot size identifying apparatus is further provided with: an edge detecting device for detecting edges of each of the frames; a connected edge detecting device for detecting connected edge areas where the detected edges are connected; and an edge area counting device for counting number of edge areas of the detected connected edge areas, said shot size specifying device specifying the frames as long shots if the counted number of edge areas is greater than first threshold for number of edge areas, or if at least one of a plurality of evaluation items preliminarily determined in regard to the specified large flat areas meets a predetermined condition.

According to this aspect, since a shot size specifying based on connected edge areas is performed in addition to a shot size specifying based on large flat areas, it is possible to reduce possibility for missing a frame of long shot, so that it is extremely useful in practice.

In this aspect, said shot size specifying device may specify the frames as long shots if the counted number of edge areas is less than second threshold for number of edge areas, and if at least one of a plurality of evaluation items preliminarily determined in regard to the specified large flat areas meets a predetermined condition.

By virtue of such construction, even if a frame is a frame whose edges is hardly detected such as a frame of long shot filmed under low light condition such as night, it is possible to reduce possibility for false-specifying or false-identifying, or missing, so that it is extremely useful in practice.

The above object of the present invention can be achieved by an electronic apparatus is provided with: the aforementioned shot size identifying apparatus (including its various aspects); and a processing device for performing a predetermined type of processing concerning at least one of reproduction of, recording of and editing of the image on the image in accordance with a specified result by said shot size specifying device.

According to the electronic apparatus of the present invention, since it is composed of the aforementioned shot size identifying apparatus of the present invention, it is possible to easily and swiftly identify a shot size. As a result, it is possible to realize various electronic apparatuses which can effectively perform image-editing operations such as a video camera which has an edit function and an assist function for filming, a motion picture reproducing apparatus, a video editing apparatus, a video server and a video storage apparatus.

The above object of the present invention can be achieved by first shot size identifying method is provided with: an edge detecting process of detecting edges which exist in each of frames constituting an image; an edge area counting process of counting number of edge areas which is total number of connected edge areas where the detected edges are connected for every frames; and a shot size specifying process of specifying the frames as long shots if the counted number of edge areas is greater than first threshold for number of edge areas.

According to the first shot size identifying method of the present invention, it is possible to easily and swiftly identify a shot size in a similar way to the first shot size identifying apparatus of the present invention as described above.

Incidentally, in the first shot size identifying method of the present invention, it is possible to adopt various aspects which are similar to various aspects of the first shot size identifying apparatus of the present invention as described above.

The above object of the present invention can be achieved by second shot size identifying method is provided with: a flatness calculating process of calculating index values indicating flatness in each of frames constituting an image for every predetermined units which are composed of one pixel or a plurality of adjoining pixels constituting each of the frames; a binarizing process of converting the calculated index values into binary; a large flat area specifying process of specifying areas where total number of the predetermined units is greater than or equal to a predetermined threshold as large flat areas from connected flat areas, where the predetermined units of which the binary index value is identical are connected; and a shot size specifying process of specifying the frames which have the specified large flat areas as long shots if at least one of a plurality of evaluation items preliminarily determined in regard to the specified large flat areas meets a predetermined condition.

According to the second shot size identifying method of the present invention, it is possible to easily and swiftly identify a shot size in a similar way to the second shot size identifying apparatus of the present invention as described above.

Incidentally, in the second shot size identifying method of the present invention, it is possible to adopt various aspects which are similar to various aspects of the second shot size identifying apparatus of the present invention as described above.

The above object of the present invention can be achieved by a computer program making a computer function as the shot size identifying apparatus of the present invention as described above (including its various aspects).

According to the computer program of the present invention, it is possible to relatively easily realize the aforementioned shot size identifying apparatus of the present invention, by loading the computer program from a recording medium for storing the computer program, such as a CD-ROM (Compact Disc Read Only Memory), a DVD-ROM (Digital Versatile Disc Read Only Memory) or the like, into the computer of a shot size identifying apparatus, or by downloading the computer program through a communication device. Thus, it is possible to easily and swiftly identify shot size in a similar way to the aforementioned shot size identifying apparatus of the present invention.

The operation and other advantages of the present invention will become more apparent from Best Mode for Carrying Out the Invention described below.

### BRIEF DESCRIPTION OF DRAWINGS

FIG. 1 is a block diagram showing the structure of a video camera of an embodiment.

FIG. 2 is a conceptual view showing schematically one example of a block in frame imageries of the embodiment.

FIG. 3 is a conceptual view showing one example of an evaluation item for large flat areas of the embodiment.

FIG. 4 is a conceptual view showing one example of a table of shot size identifying of the embodiment.

FIG. 5 is a flowchart showing a long shot detecting processing for edge areas in a shot size identifying apparatus of the embodiment.

FIG. 6 is a flowchart showing a long shot detecting processing for flat areas in the shot size identifying apparatus of the embodiment.

FIG. 7 is a flowchart showing an close-up shot detecting processing in the shot size identifying apparatus of the embodiment.

FIG. 8 is a flowchart showing a shot size identifying processing in the shot size identifying apparatus of the embodiment.

### DESCRIPTION OF REFERENCE CODES

1 video camera
10 shot size identifying apparatus
20 photographic device
30 controller
40 storage device
50 displaying device
60 operation panel

### BEST MODE FOR CARRYING OUT THE INVENTION

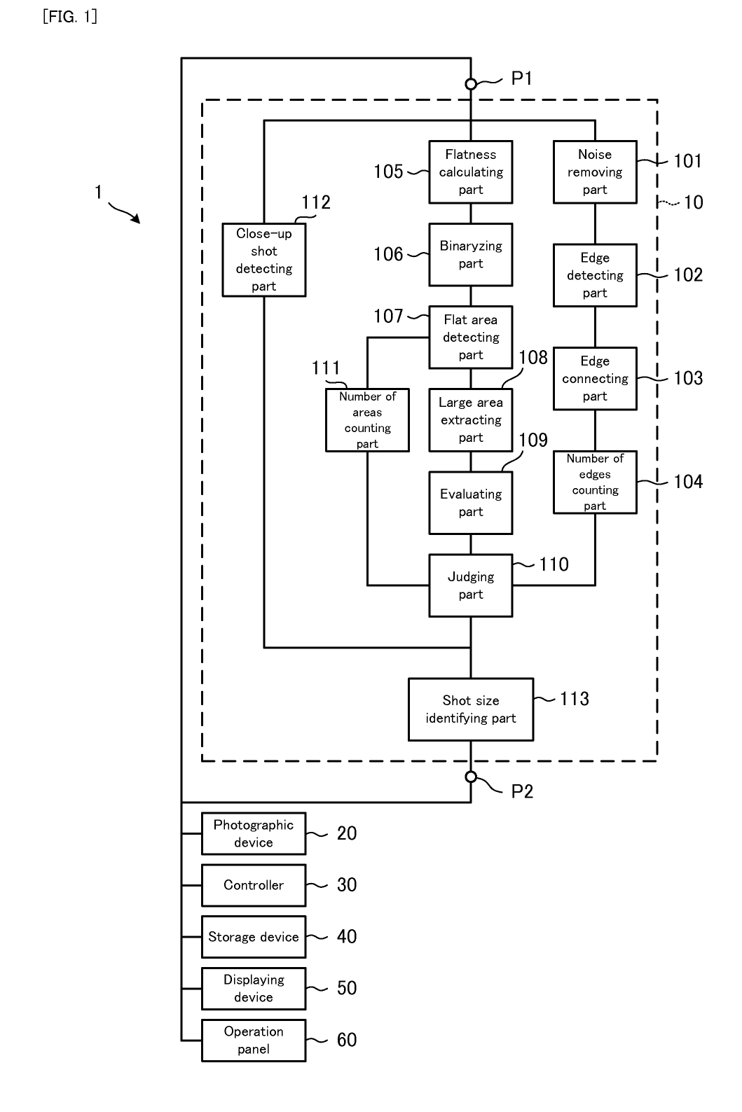

Hereinafter, an embodiment of a video camera which is one example of an electronic apparatus provided with the shot size identifying apparatus of the present invention will be described with reference to FIG. 1 to FIG. 8.

First, with reference to FIG. 1, the explanation will be given on the structure of a video camera of the embodiment. FIG. 1 is a block diagram showing the structure of the video camera of the embodiment.

In FIG. 1, the video camera 1 is provided with a shot size identifying apparatus 10, a photographic device 20, a controller 30, a storage device 40, a displaying device 50 and an operation panel 60. The shot size identifying apparatus 10 is provided with a noise removing part 101, an edge detecting part 102, a edge connecting part 103, a number of edges detecting part 104, a flatness calculating part 105, a binarizing part 106, a flat area detecting part 107, a large area extracting part 108, an evaluating part 109, a judging part 110, a number of areas counting part 111, an close-up shot detecting part 112 and a shot size identifying part 113.

Here, the “noise removing part 101”, the “edge detecting part 102”, the “edge connecting part 103”, the “number of edges detecting part 104”, the “flatness calculating part 105”, the “binarizing part 106”, the “flat area detecting part 107”, the “large area extracting part 108”, the “judging part 110”, the “number of areas counting part 111” and the “shot size identifying part 113” of the embodiment are one example of the “noise removing device”, the “edge detecting device”, the “connected edge detecting device”, the “number of edge areas counting device”, the “flatness calculating device”, the “binarizing device”, the “connected flat area detecting device”, the “large flat area extracting device”, the “judging device”, the “number of flat areas counting device” and the “shot size identifying device” of the present invention, respectively.

The photographic device 20 is composed of, for example, a lens and a CCD (Charge Coupled Device). The photographic device 20 is constructed to film motion pictures or sequential photographs, and to generate frame imageries which arrayed on a time axis at predetermined intervals or regular intervals and which is one example of the “frame” of the present invention.

The storage device 40 is a HDD (Hard Disk Drive) or a nonvolatile memory for example. The storage device 40 successively stores the motion pictures or the like which are generated by the photographic device 20.

The controller 30 controls the photographic device 20 in accordance with a command from a user accepted via the operation panel 60, or displays the motion pictures or the like which are filmed by the photographic device 20 on the displaying device 50, which is for example a LCD (Liquid Crystal Display) or the like. Alternatively, the controller 30 controls the shot size identifying apparatus 10 to identify shot size of the filmed motion pictures or the like.

At the time when a request for shot size identifying is accepted by the operation panel 60, the controller 30 controls the shot size identifying apparatus 10 to read motion pictures (or sequential photographs) stored in the storage device 40.

### (Long Shot Detecting Processing for Edge Areas)

The noise removing part 101 removes noise of a frame imagery of a motion picture, which is read via an input terminal P1 of the shot size identifying apparatus 10, by using a well-known noise removing method. Then, the edge detecting part 102 detects edges by applying a well-known edge detection to each of frame imageries from which noise is removed.

Next, the edge connecting part 103 detects edges which connect each other as one connected edge area from detected edges. Then, the number of edges counting part 104 counts the number of edge areas of the detected connected edge area by performing such as a labeling processing.

The judging part 110 judges whether or not the counted number of edge areas is greater than first threshold for number of edge areas. If it is judged that it is greater than the first threshold for number of edge areas, a frame imagery is specified as long shots. Incidentally, it is preferable that the first threshold for number of edge areas is, for example, the sum of an average value and standard deviation of the number of edge areas in the last five frame imageries or all frame imageries. The first threshold for number of edge areas may be a value which is determined on the basis of the resolution of frame imageries.

If it is judged that it is less than the first threshold for number of edge areas, the judging part 110, then, judges whether or not the counted number of edge areas is less than second threshold for number of edge areas, which is less than the first threshold for number of edge areas. If it is judged that it is less than the second threshold for number of edge areas, a frame imagery is judged that it is considered for middle shots. Incidentally, the second threshold for number of edge areas is set in a similar way to the first threshold for number of edge areas.

If it is judged that it is greater than the second threshold for number of edge areas, a frame imagery is judged that it would not be long shots.

### (Long Shot Detecting Processing for Flat Areas)

The flatness calculating part 105 calculates flatness, which is one example of the “index value” of the present invention, of frame imageries of the motion picture which is read via the input terminal P1 of the shot size identifying apparatus 10 for each block, which is one example of the “predetermined unit” of the present invention.

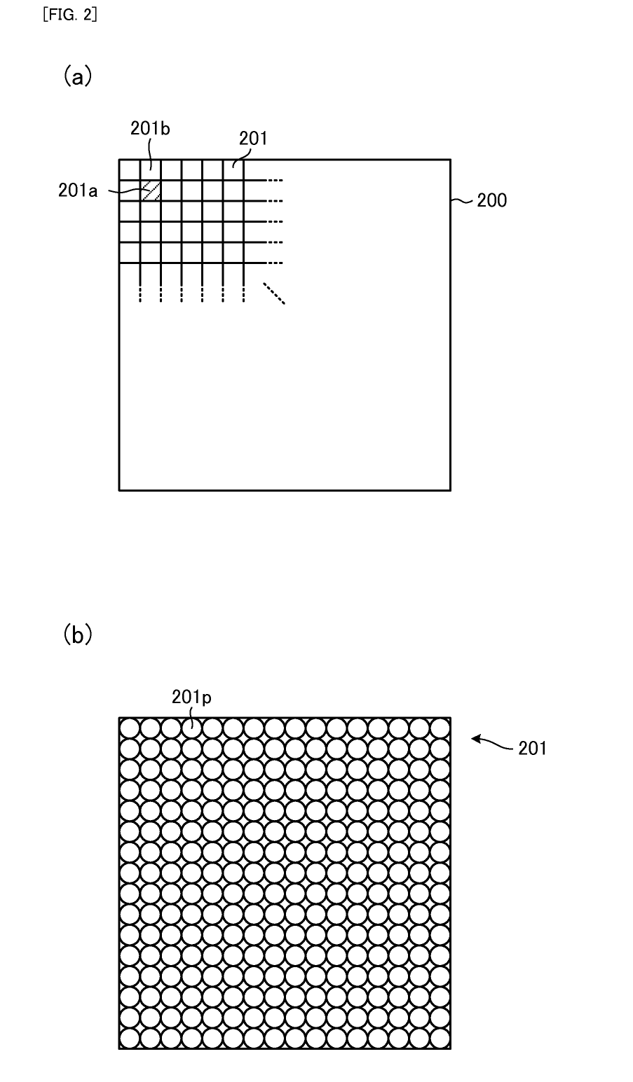

Here, with reference to FIG. 2, the additional explanation will given on the block. FIG. 2 is a conceptual view showing schematically one example of the block in frame imageries of the embodiment.

In FIG. 2(a), the frame imagery 200 is divided into a plurality of blocks 201. As shown in FIG. 2(b), the block 201 is composed of a predetermined number of pixels 201p (here, 16 pixels long by 16 pixels width) which consist the frame imagery 200.

Incidentally, the flatness calculating part 105 typically determines a color density value, a brightness value or the like of each of blocks by calculating an average value of color density values, brightness values or the like of each of the plurality of pixels 201p in the block 201 when the frame imagery 200 is divided into the plurality of blocks 201.

The flatness of each of blocks 201 on this frame imagery 200 is determined as follows: for example focus attention on the block 201a, first, the absolute value of the difference value between the value of one or more predetermined parameters of parameters, which include such as a color density value, a brightness value, of the block 201a; the value of the predetermined parameter(s) of the adjoining block 201b is calculated; the similar processing is performed on blocks which adjoin the block 201a; next, the flatness of the block 201a is determined by calculating the average value of the absolute values of a plurality of calculated difference values. Incidentally, in calculating the difference value, the flatness calculating part 105 applies two-dimensional discrete cosine transform or discrete Fourier transform to image signal indicating the color density value, the brightness value or the like of each of blocks 201. The calculating part 105 determines the difference value by calculating ratio between the power of a lower frequency component and the power of a higher frequency component not including the lower frequency component for adjoining blocks.

Return to FIG. 1 again, the binarizing part 106 converts the calculated flatness into binary. The flat area detecting part 107 extracts blocks which have identical binary flatness, and then detects connected flat areas where the extracted blocks are connected. Specifically, the flat area detecting part 107 detects flat areas by performing a labeling processing on the binary frame imagery 200.

Next, the large area extracting part 108 extracts an area where the number of blocks included in the detected connected flat area is greater than or equal to a threshold for number of blocks (e.g. 200 blocks), which is one example of the “threshold for number of units” of the present invention, as large flat areas.

Next, the evaluating part 109 gives a plurality of evaluation values corresponding to each of a plurality of evaluation items for the extracted large flat area.

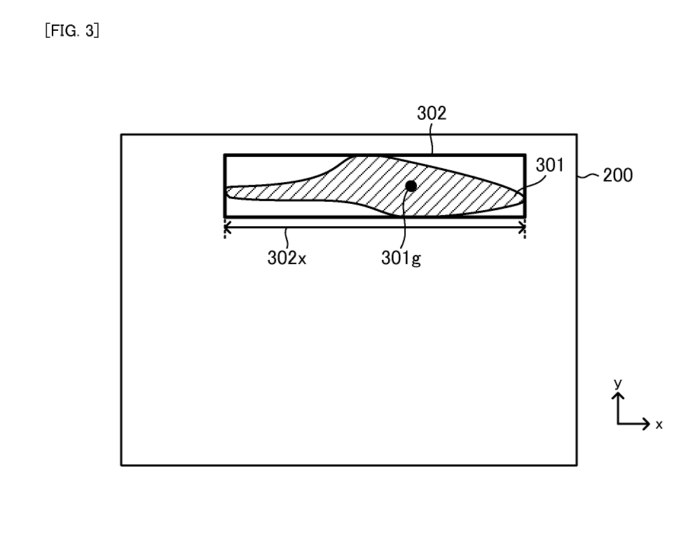

Here, with reference to FIG. 3, the additional explanation will be given on the plurality of evaluation items. FIG. 3 is a conceptual view showing one example of an evaluation item for large flat areas of the embodiment.

The evaluating part 109 gives evaluation values corresponding to area ratio between area of the large flat area 301 and area of the circumscribed rectangle 302 circumscribed the large flat area 301, the horizontal width 302x of the circumscribed rectangle 302, the barycentric position of the barycenter 301g of the large flat area 301, and the like for the large flat area 301 on the frame imagery 200.

Return to FIG. 1 again, the number of areas counting part 111 counts the number of connected flat areas detected by the flat area detecting part 107.

The judging part 106 judges whether or not at least one of the plurality of evaluation items, which are given for the large flat area 301, meets a predetermined condition corresponding to the evaluation item. Here, the predetermined condition is that the area ratio is greater than or equal to an area ratio threshold (e.g. 0.4) if the evaluation value is area ratio; the horizontal width 302x is greater than or equal to a horizontal width threshold (e.g. 30 blocks) if the evaluation value is the horizontal width 302x; the barycentric position is within a predetermined range of the frame imagery 200 (e.g. the barycenter 301g extents in upper one third of or lower one third of the frame imagery 200) if the evaluation value is the barycentric position of the barycenter 301g.

The judging part 106 further judges whether or not the number of flat areas, which is counted by the number of areas counting part 111, is less than or equal to a threshold for number of flat areas (e.g. 10). If it is judged that at least one evaluation item meets the predetermined condition, and if it is judged that the counted number of flat areas is less than or equal to the threshold for number of flat areas, the frame imagery 200 which has the large flat area 301 is judged that it is considered for long shots. On the other hand, if evaluation items do not meet predetermined conditions, or if the counted number of flat areas is greater than the threshold for number of flat areas, the frame imagery 200 is judged that it would not be long shots.

(Close-up shot Detecting Processing)

The close-up shot detecting part 102 detects close-up shots by performing a predetermined close-up shot detection on frame imageries of the motion picture which is read via the input terminal P1 of the shot size identifying apparatus 10, thereby the close-up shot detecting part 102 detects close-up shots. Specifically, for example, the close-up shot detecting part 102 detects close-up shots as follows: a flesh colored area on a frame imagery is detected; it is judged whether or not area, the shape, the position and the like of the flesh colored area meet conditions corresponding to each of them; the frame imagery is detected as close-up shots if it is judged that the flesh colored area meets predetermined conditions. Alternatively, the close-up shot detecting part 102 detects close-up shots as follows: a moving object is detected on the basis of difference values of a plurality of frame imageries; it is judged whether or not area, the shape, the position and the like of the moving object meet conditions corresponding to each of them; it is detected as a frame imagery which is considered for close-up shots if it is judged that the moving object meets conditions.

On the other hand, the frame imagery is judged that it would not be close-up shots if it is judged that the flesh colored area does not meet predetermined conditions, or if it is judged that the moving object does not meet conditions.

### (Shot Size Identifying Processing)

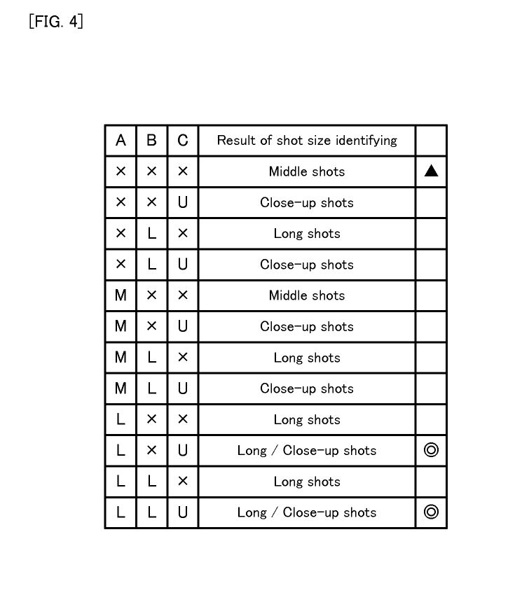

As a simple method, the shot size identifying part 113 identifies the shot size of a frame imagery with reference to a table of shot size identifying, as shown in FIG. 4, which stored in such as the non-illustrated memory of the shot size identifying part 113, on the basis of result of each of the long shot detecting processing for edge areas, the long shot detecting processing for flat areas and the close-up shot detecting processing as described above.

FIG. 4 is a conceptual view showing one example of a table of shot size identifying of the embodiment. In FIG. 4, each of A, B and C indicates judged result of each of the long shot detecting processing for edge areas, the long shot detecting processing for flat areas and the close-up shot detecting processing. Moreover, each of L, M and U indicates each of judged results that “it is considered for long shots”, “it is considered for middle shots” and “it is considered for close-up shots”. Moreover X indicates the judged result that “it would not be long shots” or “it would not be close-up shots”. Specifically, the shot size identifying part 113 identifies the following frame imageries as long shots: a frame imagery that the result of the long shot detecting processing for flat areas is that “it is considered for long shots” and the result of the close-up shot detecting processing is that “it is not close-up shot at least”; a frame imagery that the result of the long shot detecting processing for edge areas is that “it is considered for long shots”, the result of the long shot detecting processing for flat areas is that “it is considered for long shots”, and the result of the close-up shot detecting processing is that “it would not be close-up shots”. The shot size identifying part 113 outputs a result via an output terminal P2. The outputted result is displayed on the displaying device 50 by the controller 30, or is stored in the storage device 40.

The shot size identifying part 113 identifies the following frame imagery as “long/close-up shots”: a frame imagery that the result of long shot detecting processing for edge areas is that “it is considered for long shots”, and the result of the close-up shot detecting processing is that “it is considered for close-up shots”. Incidentally, in this case (i.e. the case indicated by “⊚” in FIG. 4), the shot size identifying part 113 may identify the frame imagery as “middle shots”, or may exclude the frame imagery from targets of the shot size identifying processing.

The shot size identifying part 113 identifies the following frame imagery as middle shots: a frame imagery that the result of the long shot detecting processing for edge areas is that “it is considered for middle shots”, the result of the long shot detecting processing for flat areas is that “it is not long shot at least”, and the result of the close-up shot detecting processing is that “it is not close-up shot at least”.

The shot size identifying part 113 identifies the following frame imagery as close-up shots: a frame imagery that the result of the long shot detecting for edge area is that “it is considered for middle shots” or “it would not be long shots”, and the result of the close-up shot detecting processing is that “it is considered for close-up shots”.

The shot size identifying part 113 identifies the following frame imagery as middle shots: a frame imagery that both results of the long shot detecting processing for edge areas and the long shot detecting processing for flat areas are that “it would not be long shots”, and the result of the close-up shot detecting processing is that “it would not be close-up shots”. Incidentally, in this case (i.e. the case indicated by “▴” in FIG. 4), the frame imagery may be excluded from targets of the shot size identifying processing.

Incidentally, the shot size identifying part 113 may identify the shot size of a frame imagery in accordance with the detected area, the counted number of areas or the like in each of the long shot detecting processing for edge areas, the long shot detecting processing for flat areas and the close-up shot detecting processing in addition to or in place of the table of shot size identifying as shown in FIG. 4.

Moreover, in addition to or in place of the shot size identifying for each frame imagery as described above, the shot size identifying part 113 may determines the shot size in some shot interval by judging the result of each of the long shot detecting processing for edge areas, the long shot detecting processing for flat areas and the close-up shot detecting processing in the shot interval comprehensively. Specifically, the most common result of the shot size detecting in some shot interval is adopted as the shot size of the shot interval.

Alternatively, for example, it is assumed as follows: a case in which the result of the long shot detecting processing for edge areas is that “it is considered for long shots” is indicated by −5; a case in which the result of the long shot detecting processing for flat areas is that “it is considered for long shots” is indicated by −4; a case in which the result of the long shot detecting processing for edge areas is that “it is considered for middle shots” is indicated by 0; and a case in which the result of the close-up shot detecting processing is that “it is considered for close-up shots” is indicated by +4.

Then, weight is given in accordance with degree of association between each of detecting parameters and shot sizes. The shot size identifying part 113 may identify as follows: if the arithmetic weighted mean is negative value in some shot interval, the shot size of the shot interval is long shots; if the arithmetic weighted mean is ±0 in some shot interval, the shot size of the shot interval is middle shots; and if the arithmetic weighted mean is positive value in some shot interval, the shot size of the shot interval is close-up shots. Moreover, the absolute value of the average value may be treated as degree of reliability of a detected result.

Incidentally, the “shot interval” typically means an interval in which shot size is constant. At the border of the shot interval, generally, since switch of camera work is occurred, the shot interval may be detected by detecting the border by using the well-known camera work detection, a scene change detection or the like.

As a result, according to the embodiment, it is possible to easily and swiftly identify shot size. Therefore, it is possible to provide the video camera 1, which can effectively perform image-editing operations.

Incidentally, in addition to the electronic apparatus explained with reference to FIG. 1, a motion picture reproducing apparatus, a video editing apparatus, a video server, a video storage apparatus and the like are pointed to as an example of the electronic apparatus. It is obvious that the present invention can be applied to these various electronic apparatuses.

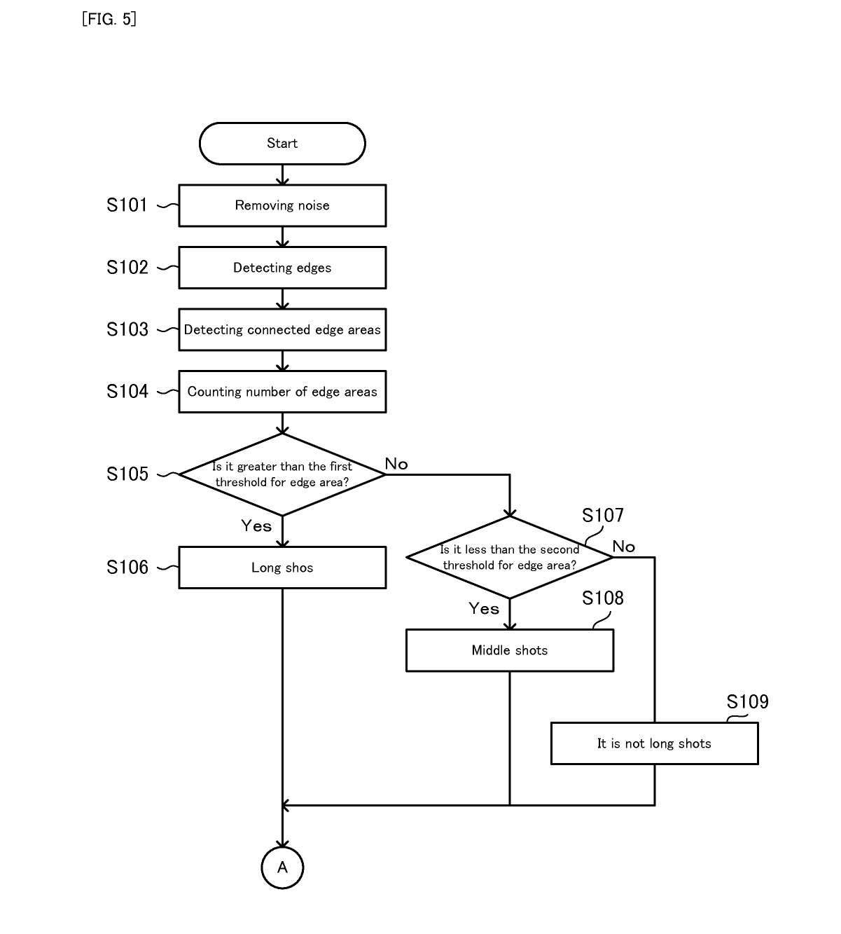

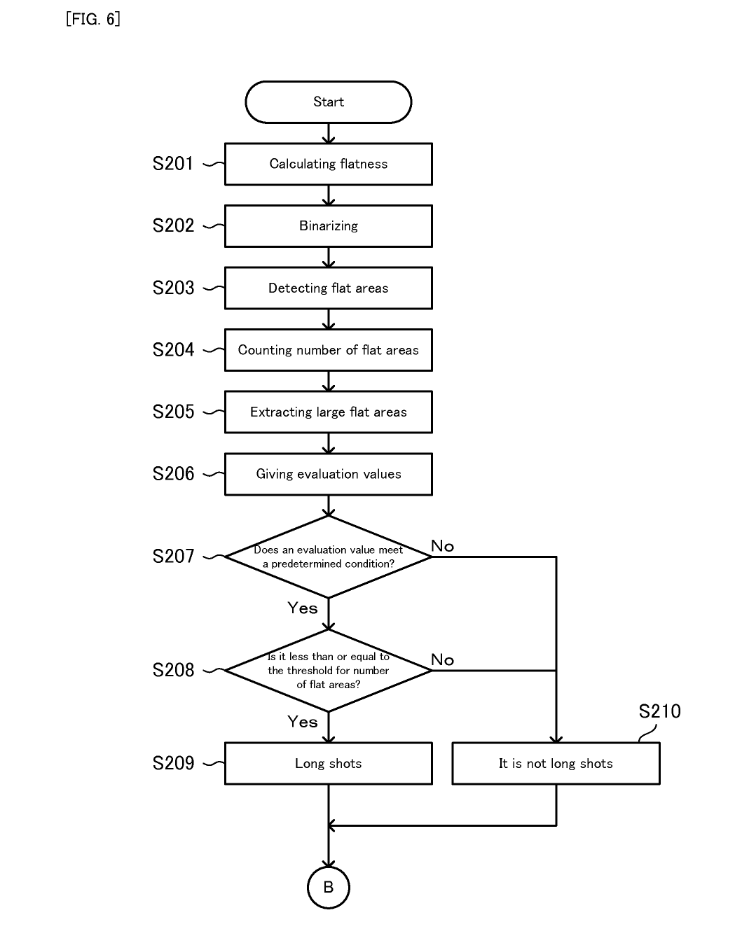

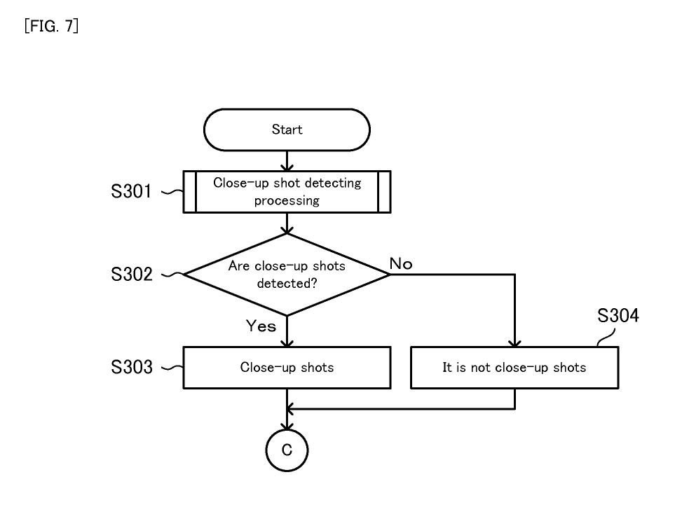

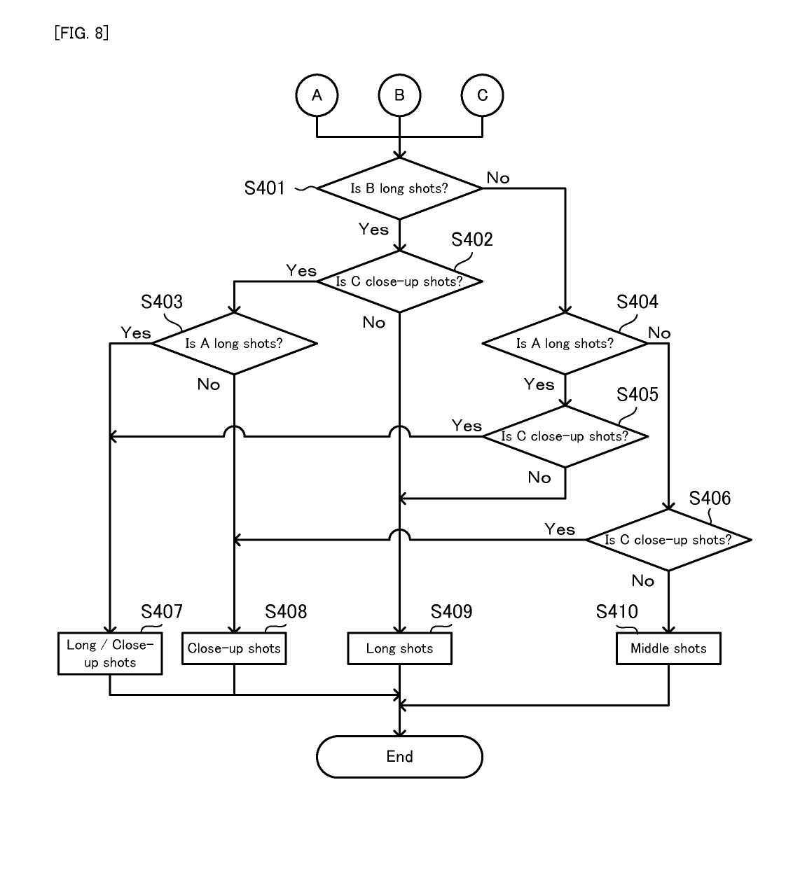

Next, the additional explanation will be given on the operation of the shot size identifying apparatus 10, which is installed in the video camera 1 constructed in the above manner with reference to FIG. 5 to FIG. 8. FIG. 5 is a flowchart showing a long shot detecting processing for edge areas in a shot size identifying apparatus of the embodiment. FIG. 6 is a flowchart showing a long shot detecting processing for flat areas in the shot size identifying apparatus of the embodiment. FIG. 7 is a flowchart showing an close-up shot detecting processing in the shot size identifying apparatus of the embodiment. FIG. 8 is a flowchart showing a shot size identifying processing in the shot size identifying apparatus of the embodiment.

In FIG. 5, first, noise on a frame imagery constituting the read image is removed by the noise removing part 101 (step S101). Then, edges are detected by the edge detecting part 102 (step S102). Then, edges which are connected each other are detected as one connected edge area from detected edges by the edge connecting part 103 (step S103).

Next, the number of edge areas of the detected connected edge area is counted by the number of edges counting part 104 (step S104). Then, it is judged whether or not the counted number of edge areas is greater than the first threshold for number of edge areas by the judging part 110 (step S105). If it is judged that it is greater than the first threshold for number of edge areas (the step S105: Yes), the frame imagery is judged that “it is considered for long shots” (step S106).

If it is judged that it is less than the first threshold for number of edge areas (the step S105: No), then, the judging part 110 judges whether or not it is less than the second threshold for number of edge areas (step S107). If it is judged that it is less than the second threshold for number of edge areas (the step S107: Yes), the frame imagery is judged that “it is considered for middle shots” (step S108).

If it is judged that it is greater than the threshold for number of edge areas (the step S107: No), the frame imagery is judged that “it would not be long shots”.

In FIG. 6, the flatness calculating part 105 calculates flatness of the frame imagery constituting the read image for each block (step S201). Then, the calculated flatness is converted into binary by the binarizing part 106 (step S202). Next, by the flat area detecting part 107, blocks which have identical binary flatness are extracted, and then, connected flat areas where the extracted blocks are connected are detected (step S203).

Next, the number of flat areas of the detected connected flat area is counted by the number of areas counting part 111 (step S204). By the large flat area extracting part 108, a connecting flat area where the number of blocks included in a detected connected flat area is greater than or equal to the threshold for number of blocks is extracted as a large flat area almost as soon as the counting the number of flat areas (step S205).

Next, a plurality of evaluation values corresponding to each of a plurality of evaluation items are given for an extracted large flat area by the evaluating part 109 (step S206). Then, it is judged whether or not a given evaluation value meets a predetermined condition by the judging part 110 (step S207). If it is judged that the given evaluation value does not meet the predetermined condition (the step S207: No), the frame imagery is judged that “it would not be long shots” (step S210).

If it is judged that the given evaluation value meets the predetermined condition (the step S207: Yes), then, it is judged whether or not the counted number of flat areas is less than or equal to the threshold for number of flat areas by the judging part 110 (step S208). If it is judged that it is greater than the threshold for number of flat areas (the step S208: No), the frame imagery is judged that “it would not be long shots” (the step S210).

If it is judged that it is less than or equal to the threshold for number of flat areas (the step S208: Yes), the frame imagery is judged that “it is considered for long shots” (step S209). Incidentally, processing of each of the step S207 and the step S208 can be performed whichever first.

In FIG. 7, a predetermined close-up shot detecting processing is performed on the frame imagery constituting the read image by the close-up shot detecting part 112 (step S301). Then, it is judged whether or not an close-up shot is detected (step S302). If it is judged that an close-up shot is detected (the step S302: Yes), the frame imagery is judged that “it is considered for close-up shots” (step S303). If it is judged that an close-up shot is not detected (the step S302: No), the frame imagery is judged that “it would not be close-up shots” (step S304).

The shot size identifying part 113 identifies the shot size of the frame imagery by performing a processing, which will be described below, on the basis of result of each of the long shot detecting processing for edge areas, the long shot detecting processing for flat areas and the close-up shot detecting processing.

In FIG. 8, first, it is judged whether or not the result of the long shot detecting processing for flat areas is that “it is considered for long shots” (step S401). If it is judged that the result is “it is considered fro long shots” (the step S401: Yes), then, it is judged whether or not the result of the close-up shot detecting processing is that “it is considered for close-up shots” (step S402).

If it is judged that the result of the close-up shot detecting processing is not that “it is considered for close-up shots” (the step S402: No), the frame imagery is identified as long shots (step S409). Then, the result is outputted and the processing is performed on another frame imagery.

If it is judged that the result of the close-up shot detecting processing is that “it is considered for close-up shots” (the step S402: Yes), then, it is judged whether or not the result of the long shot detecting processing for edge areas is that “it is considered for long shots” (step S403). If it is judged that the result is that “it is considered for long shots” (the step S403: Yes), the frame imagery is identified as long/close-up shots (step S407). Then, the result is outputted and the processing is performed on another frame imagery.

On the other hand, if it is judged that the result of the long shot detecting processing for edge areas is not that “it is considered for long shots” i.e. if the result of the long shot detecting processing for edge areas is that “it is considered for middle shots” or “it would not be long shots” (the step 5403: No), the frame imagery is identified as close-up shots (step S408). Then, the result is outputted and the processing is performed on another frame imagery.

If it is judged that the result of the long shot detecting processing for flat areas is not that “it is considered for long shots” (the step 5401: No), then, it is judged whether or not the result of the long shot detecting processing for edge areas is that “it is considered for long shots” (step S404). If it is judged that the result is that “it is considered for long shots” (the step 5404: Yes), then, it is judged whether or not the result of the close-up shot detecting processing is that “it is considered for close-up shots” (step S405).

If it is judged that the result of the close-up shot detecting processing is that “it is considered for close-up shots” (the step 5405: Yes), the frame imagery is identified as long/close-up shots (the step S407). Then, the result is outputted and the processing is performed on another frame imagery. On the other hand, if it is judged that the result of the close-up shot detecting processing is not that “it is considered for close-up shot” (the step 5405: No), the frame imagery is identified as long shots (the step S409). Then, the result is outputted and the processing is performed on another frame imagery.

If it is judged that the result of the long shot detecting processing for edge areas is not that “it is considered for long shots” (the step 5404: No), then, it is judged whether or not the result of the close-up shot detecting processing is that “it is considered for close-up shots” (step S406). If it is judged that the result is that “it is considered for close-up shots” (the step S406: Yes), the frame imagery is identified as close-up shots (the step S408). Then, the result is outputted and the processing is performed on another frame imagery.

On the other hand, if it is judged that the result of the close-up shot detecting processing is not that “it is considered for close-up shots” (the step S406: No), the frame imagery is identified as middle shots (step S410). Then, the result is outputted and the processing is performed on another frame imagery.

Incidentally, the present invention is not limited to the aforementioned embodiment, but various changes may be made, if desired, without departing from the essence or spirit of the invention which can be read from the claims and the entire specification. A shot size identifying apparatus and method, an electronic apparatus and a computer program, all of which involve such changes, are also intended to be within the technical scope of the present invention.

1-22. (canceled)

23. A shot size identifying apparatus comprising:
an edge detecting device for detecting edges which exist in each of frames constituting an image;
a connected edge area detecting device for detecting connected edge areas where the detected edges are connected;
an edge area counting device for counting number of edge areas which is total number of the detected connected edge areas for every the frames; and
a shot size specifying device for specifying a frame in which the counted number of edge areas is greater than first threshold for number of edge areas as long shots.

24. The shot size identifying apparatus according to claim 23, said shot size specifying device comprising:
a judging device for judging whether or not the counted number of edge areas is greater than the first threshold for number of edge areas; and
a shot size identifying device for identifying a frame which is judged that the counted number of edge areas is greater than the first threshold for number of edge areas as long shots.

25. The shot size identifying apparatus according to claim 23, wherein the first threshold for number of edge areas is determined on the basis of a parameter of the frames.

26. The shot size identifying apparatus according to claim 23, wherein the first threshold for number of edge areas is changeable in accordance with a parameter indicating a predetermined statistical value of the frames.

27. The shot size identifying apparatus according to claim 23, wherein the shot size specifying device specifies a frame in which the counted number of edge areas is less than second threshold for number of edge areas as middle shots.

28. The shot size identifying apparatus according to claim 27, wherein the second threshold for number of edge areas is less than the first threshold for number of edge areas.

29. The shot size identifying apparatus according to claim 23, further comprising: a noise removing device for removing noise of each of the frames.

30. A shot size identifying apparatus comprising:
a flatness calculating device for calculating index values indicating flatness in each of frames constituting an image for every predetermined units which are composed of one pixel or a plurality of adjoining pixels constituting each of the frames;
a binarizing device for converting the calculated index values into binary;
a large flat area specifying device for specifying areas where total number of the predetermined units is greater than or equal to a threshold for number of units as large flat areas from connected flat areas where the predetermined units of which the binary index value is identical are connected; and
a shot size specifying device for specifying a frame which has a large flat area where at least one of a plurality of evaluation items preliminarily determined in regard to the specified large flat areas meets a predetermined condition as long shots.

31. The shot size identifying device according to claim 30, said large flat area specifying device comprising:
a connected flat area detecting device for detecting the connected flat areas; and
a large flat area extracting device for extracting areas where number of the predetermined units is greater than or equal to the threshold for number of units as large flat areas from the detected connected flat areas.

32. The shot size identifying apparatus according to claim 30, said shot size specifying device comprising:
a judging device for judging whether or not the specified large flat areas meet the predetermined condition corresponding to at least one of the plurality of evaluation items; and
a shot size identifying device for identifying a frame which has a large flat area which is judged that it meets the predetermined condition as long shots.

33. The shot size identifying apparatus according to claim 30, wherein
the plurality of evaluation items includes area ratio between area of the specified large flat area and area of a rectangle which is circumscribed the extracted large flat area, and
the predetermined condition is that the area ratio is greater than or equal to an area ratio threshold.

34. The shot size identifying apparatus according to claim 30, wherein
the plurality of evaluation items includes a horizontal width of a rectangle which is circumscribed the specified large flat area, and
the predetermined condition is that the horizontal width is greater than or equal to a horizontal width threshold.

35. The shot size identifying apparatus according to claim 30, wherein
the plurality of evaluation items includes a barycentric position of the specified large flat area, and
the predetermined condition is that the barycentric position is within a predetermined range.

36. The shot size identifying apparatus according to claim 30, wherein said flatness calculating device calculates the index values by performing frequency analysis on each of the predetermined units.

37. The shot size identifying apparatus according to claim 36, wherein the frequency analysis includes two-dimensional discrete cosine transform or discrete Fourier transform.

38. The shot size identifying apparatus according to claim 30, further comprising: a number of flat areas counting device for counting number of flat areas in each of the detected connected flat areas,
said shot size specifying device specifying a frame which has a large flat area in which the counted number of flat areas is less than or equal to a threshold for number of flat areas as long shots when at least one of the plurality of evaluation items meets the predetermined condition.

39. The shot size identifying apparatus according to claim 30, further comprising:
an edge detecting device for detecting edges of each of the frames;
a connected edge detecting device for detecting connected edge areas where the detected edges are connected; and
an edge area counting device for counting number of edge areas of the detected connected edge areas, said shot size specifying device specifying a frame in which the counted number of edge areas is greater than first threshold for number of edge areas, or in which at least one of the plurality of evaluation items meets the predetermined condition as long shots.

40. The shot size identifying apparatus according to claim 39, wherein said shot size specifying device specifies a frame in which the counted number of edge areas is less than second threshold for number of edge areas, and in which at least one of the plurality of evaluation items meets the predetermined condition as long shots.

41. An electronic apparatus comprising:
a shot size identifying apparatus comprising: an edge detecting device for detecting edges which exist in frames constituting an image; a connected edge area detecting device for detecting connected edge areas where the detected edges are connected; an edge area counting device for counting number of edge areas which is total number of the detected connected edge areas for every the frames; and a shot size specifying device for specifying a frame in which the counted number of edge areas is greater than first threshold for number of edge areas as long shots; and
a processing device for performing a predetermined type of processing concerning at least one of reproduction of, recording of and editing of the image on the image in accordance with a specified result by said shot size specifying device.

42. A shot size identifying method comprising:
an edge detecting process of detecting edges which exist in each of frames constituting an image;
an edge area counting process of counting number of edge areas which is total number of connected edge areas where the detected edges are connected for every the frames; and
a shot size specifying process of specifying a frame in which the counted number of edge areas is greater than first threshold for number of edge areas as long shots.

43. A shot size identifying method comprising:
a flatness calculating process of calculating index values indicating flatness in each of frames constituting an image for every predetermined units which are composed of one pixel or a plurality of adjoining pixels constituting each of the frames;
a binarizing process of converting the calculated index values into binary;
a large flat area specifying process of specifying areas where total number of the predetermined units is greater than or equal to a threshold for number of units as large flat areas from connected flat areas where the predetermined units which have identical the binary index value are connected; and
a shot size specifying process of specifying a frame which has a large flat areas where at least one of a plurality of evaluation items preliminarily determined in regard to the specified large flat areas meets a predetermined condition as long shots.

44. A computer-readable medium containing a computer program for making a computer function as a shot size identifying apparatus comprising: an edge detecting device for detecting edges which exist in each of frames constituting an image; a connected edge area detecting device for detecting connected edge areas where the detected edges are connected; an edge area counting device for counting number of edge areas which is total number of the detected connected edge areas for every the frames; and a shot size specifying device for specifying a frame in which the counted number of edge areas is greater than first threshold for number of edge areas as long shots.

45. An electronic apparatus comprising:
a shot size identifying apparatus comprising: a flatness calculating device for calculating index values indicating flatness in each of frames constituting an image for every predetermined units which are composed of one pixel or a plurality of adjoining pixels constituting each of the frames; a binarizing device for converting the calculated index values into binary; a large flat area specifying device for specifying areas where total number of the predetermined units is greater than or equal to a threshold for number of units as large flat areas from connected flat areas where the predetermined units of which the binary index value is identical are connected; and a shot size specifying device for specifying a frame which has a large flat area where at least one of a plurality of evaluation items preliminarily determined in regard to the specified large flat areas meets a predetermined condition as long shots; and
a processing device for subjecting the image to a predetermined type of processing concerning at least one of reproduction of, recording of and editing of the image in accordance with a specified result by said shot size specifying device.

46. A computer-readable medium containing a computer program for making a computer function as a shot size identifying apparatus comprising: a flatness calculating device for calculating index values indicating flatness in each of frames constituting an image for every predetermined units which are composed of one pixel or a plurality of adjoining pixels constituting each of the frames; a binarizing device for converting the calculated index values into binary; a large flat area specifying device for specifying areas where total number of the predetermined units is greater than or equal to a threshold for number of units as large flat areas from connected flat areas where the predetermined units of which the binary index value is identical are connected; and a shot size specifying device for specifying a frame which has a large flat area where at least one of a plurality of evaluation items preliminarily determined in regard to the specified large flat areas meets a predetermined condition as long shots.
